(19) United States
(12) Patent Application Publication
(10) Pub. No.: US 2026/0156865 A1
(43) Pub. Date: Jun. 4, 2026

(54) ARRAY SUBSTRATE AND DISPLAY PANEL

(71) Applicant: WUHAN CHINA STAR OPTOELECTRONICS TECHNOLOGY CO., LTD., Wuhan, Hubei (CN)

(72) Inventors: Yinyin YU, Wuhan, Hubei (CN); Can HUANG, Wuhan, Hubei (CN); Dewei SONG, Wuhan, Hubei (CN); Fei AI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/705,498

(22) PCT Filed: Mar. 19, 2024
(86) PCT No.: PCT/CN2024/082338

§ 371 Date: Apr. 26, 2024

(30) Foreign Application Priority Data
Mar. 13, 2024 (CN) 202410292068.5

(51) Int. Cl. H10D 30/67; H10D 86/60

(52) U.S. Cl. CPC H10D 30/6723; H10D 86/60

(57) ABSTRACT

The present disclosure provides an array substrate and a display panel. The array substrate includes a substrate, a transistor and a first light-shielding portion disposed at a side of the substrate; and the first light-shielding portion is disposed between a source and an active layer, and between a drain and the active layer. An orthographic projection of the first light-shielding portion on the substrate covers an orthographic projection of the channel region on the substrate, and exceeds a range of the orthographic projection range of the channel region on the substrate, so as to shield reflected light from the metal layer where the source and the drain are located.

### TECHNICAL FIELD

The present disclosure relates to the field of display, and in particular, to an array substrate and a display panel.

### BACKGROUND

Compared with traditional amorphous silicon (A-Si) thin film transistor technology, low-temperature polycrystalline silicon (LTPS) technology can obtain higher carrier mobility, and thus has been widely used in small and medium-sized high-resolution thin film transistor liquid crystal displays (TFT LCDs), such as virtual reality (VR) devices. VR devices require that its display device has high brightness, high pixel density (Pixels Per Inch, PPI), low power consumption and other performance. However, existing VR devices have the problem of the increasing of photogenerated leakage current under the condition of high brightness of backlight and long-time of illumination, which causes the problem of crosstalk.

### SUMMARY

The present disclosure provides an array substrate and a display panel, which can alleviate the technical problem of crosstalk caused by the increasing of photogenerated leakage current in existing thin film transistor liquid crystal displays.

To solve the above-mentioned problem, the present disclosure provides technical solutions as follows.

In a first aspect, embodiments of the present disclosure provide an array substrate including:
a substrate;
a transistor disposed at a side of the substrate and including an active layer, a source, and a drain, in which the source and the drain are disposed at a side of the active layer away from the substrate, and the active layer includes a channel region; and
a first light-shielding portion disposed between the source and the active layer, and between the drain and the active layer, in which an orthographic projection of the first light-shielding portion on the substrate covers an orthographic projection of the channel region on the substrate, and exceeds a range of the orthographic projection of the channel region on the substrate.

In a second aspect, embodiments of the present disclosure further provide a display panel including an array substrate, in which the array substrate includes:
a substrate;
a transistor disposed at a side of the substrate and including an active layer, a source, and a drain, in which the source and the drain are disposed at a side of the active layer away from the substrate, and the active layer includes a channel region; and
a first light-shielding portion disposed between the source and the active layer, and between the drain and the active layer, in which an orthographic projection of the first light-shielding portion on the substrate covers an orthographic projection of the channel region on the substrate, and exceeds a range of the orthographic projection of the channel region on the substrate.

### BRIEF DESCRIPTION OF THE DRAWINGS

In order to explain technical solutions in embodiments of the present disclosure or the prior art more clearly, the following will briefly introduce the drawings needed to be used in description of the embodiments or the prior art. Apparently, the drawings in the following description are introduced for illustrating only some embodiments of the present disclosure. For ordinary skilled in the art, other drawings can be obtained from these drawings without paying creative effort.

FIG. 1 is a schematic cross-sectional structural diagram of an array substrate in the prior art.

FIG. 2 is a schematic cross-sectional structural diagram of an array substrate provided by some embodiments of the present disclosure.

FIG. 3 is a schematic planar structural diagram of an array substrate provided by some embodiments of the present disclosure.

FIG. 4 is a schematic diagram of a light-leakage distribution of the array substrate in FIG. 1.

FIG. 5 is a schematic diagram of a light-leakage distribution of the array substrate in FIG. 3.

FIG. 6 is another schematic cross-sectional structural diagram of an array substrate provided by some embodiments of the present disclosure.

FIG. 7 is another schematic planar structural diagram of an array substrate provided by some embodiments of the present disclosure.

FIG. 8 is another schematic planar structural diagram of an array substrate provided by some embodiments of the present disclosure.

FIG. 9 is a schematic diagram of a light-leakage distribution of the array substrate in FIG. 8.

### DETAILED DESCRIPTION

Specific embodiments that can be implemented in the present disclosure are described in the following with reference to the drawings. Directional terms mentioned in the present disclosure, such as [up], [down], [front], [back], [left], [right], [inside], [outside], [side], and the like, only refer to directions of the drawings. Therefore, the directional terms are used to explain and understand the present disclosure, not to limit it. In the drawings, units with similar structures are represented by the same numeral. In the drawings, thicknesses of some layers and regions have been zoomed for clarity and ease of description. Size and thickness of each component shown in the drawings are arbitrary, and the present disclosure is not limited to this.

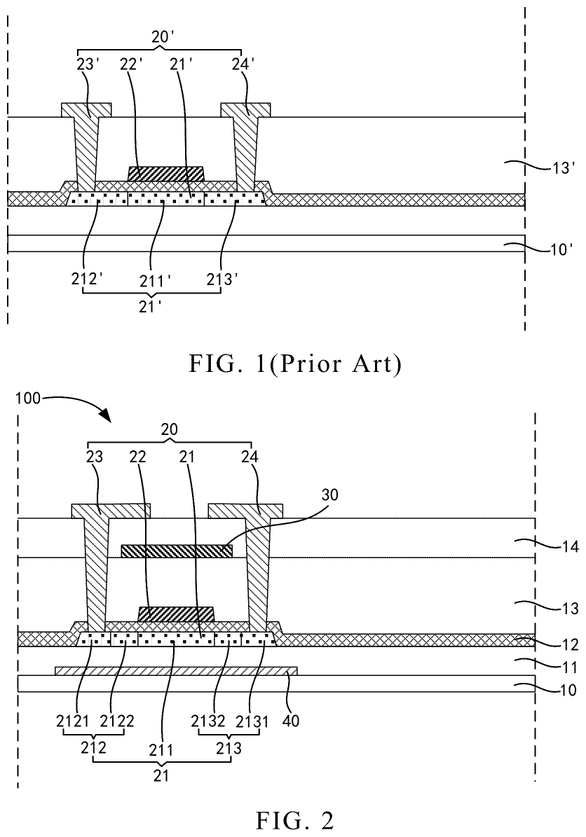

For the technical problem of crosstalk caused by the increasing of photogenerated leakage current in existing thin film transistor liquid crystal displays, the inventors of the present disclosure have found in their research that it is caused mainly by the reflection of backlight by a metal layer above an active layer in the thin-film transistor liquid crystal displays to a channel region of the active layer. Specifically, referring to FIG. 1, the array substrate includes a substrate 10′ and a thin film transistor 20′ disposed at a side of the substrate 10′. The thin film transistor 20′ includes an active layer 21′, a gate 22′, a source 23′, and a drain 24′. The gate 22′ is disposed at a side of the active layer 21′ away from the substrate 10′. The source 23′ and the drain 24′ are disposed at a side of the gate 22′ away from the substrate 10′. The active layer 21′includes a channel region 211′, and a source-doped region 212′ and a drain-doped region 213′disposed at opposite two sides of the channel region 211′. The gate 22′ is disposed corresponding to the channel region 211′, the source 23′ is connected to the source-doped region 212′, and the drain 24′ is connected to the drain-doped region 213′. When backlight reaches the metal layer where the source 23′ and the drain 24′ are located, the backlight will be reflected to the channel region 211′ of the active layer 21′, resulting in the increasing of the photogenerated leakage current in the channel region 211′, which causes the problem of crosstalk.

To solve the above-mentioned problem, the present disclosure provides an array substrate and a display panel including the array substrate.

In some embodiments, the array substrate of the present disclosure includes:
a substrate;
a transistor disposed at a side of the substrate and including an active layer, a source, and a drain, in which the source and the drain are disposed at a side of the active layer away from the substrate, and the active layer includes a channel region; and
a first light-shielding portion disposed between the source and the active layer, and between the drain and the active layer, in which an orthographic projection of the first light-shielding portion on the substrate covers an orthographic projection of the channel region on the substrate, and exceeds a range of the orthographic projection of the channel region on the substrate.

In some embodiments, the transistor further includes a gate disposed at a side of the active layer away from the substrate and corresponding to the channel region; the first light-shielding portion is disposed at a side of the gate away from the substrate; and the orthographic projection of the first light-shielding portion on the substrate covers an orthographic projection of the gate on the substrate and exceeds a range of the orthographic projection of the gate on the substrate.

In some embodiments, the array substrate further includes multiple gate scanning lines extending along a first direction and multiple data lines extending along a second direction; one of the gate scanning lines is connected to the gate and disposed in a same layer as the gate, and one of the data lines is connected to the source and disposed in a same layer as the source; and the first light-shielding portion extends along the first direction, and the orthographic projection of the first light-shielding portion on the substrate covers an orthographic projection of one of the gate scanning lines on the substrate and exceeds a range of the orthographic projection of the one of the gate scanning lines on the substrate along the second direction.

In some embodiments, the first light-shielding portion is in a long strip shape along the first direction.

In some embodiments, the first light-shielding portion is provided with at least one fracture disposed between adjacent two of the data lines, and first light-shielding portions at two sides of the fracture are separated from each other.

In some embodiments, the fracture is disposed between every adjacent two of the data lines.

In some embodiments, the array substrate further includes a second light-shielding portion disposed between the substrate and the transistor, and the second light-shielding portion is disposed corresponding to the active layer.

In some embodiments, the active layer further includes a source-doped region and a drain-doped region disposed at opposite two sides of the channel region, the source is connected to the source-doped region, and the drain is connected to the drain-doped region; and each of the source-doped region and the drain-doped region includes a heavily doped region and a lightly doped region, and the heavily doped region is disposed at a side of the lightly doped region away from the channel region.

In some embodiments, the drain is disposed at a side of the source away from the substrate.

In some embodiments, a material of the second light-shielding portion and a material of the first light-shielding portion are the same.

In some embodiments, the present disclosure further provides a display panel including one of the array substrates provided in the above-mentioned embodiments.

In the array substrate and the display panel provided in the present disclosure, the array substrate includes the substrate, and the transistor and the first light-shielding portion disposed at a side of the substrate; the transistor includes the active layer, the source, and the drain; the source and the drain are disposed at a side of the active layer away from the substrate; the active layer includes the channel region; the first light-shielding portion is disposed between the source and the active layer, and between the drain and the active layer; and the orthographic projection of the first light-shielding portion on the substrate covers the orthographic projection of the channel region on the substrate, and exceeds a range of the orthographic projection of the channel region on the substrate. By setting the first light-shielding portion between the source and the drain and the active layer, the first light-shielding portion of the present disclosure can shield the light reflected from the metal layer where the source and the drain are located, so as to reduce light of the backlight reflected into the channel region through the metal layer where the source and the drain are located, thereby reducing the photogenerated leakage current of transistor devices, improving electrical property of the devices, and alleviating the technical problem of crosstalk caused by the increasing of photogenerated leakage current in existing thin film transistor liquid crystal displays.

The array substrate and the display panel of the present disclosure will be described in specific embodiments in combination with the drawings.

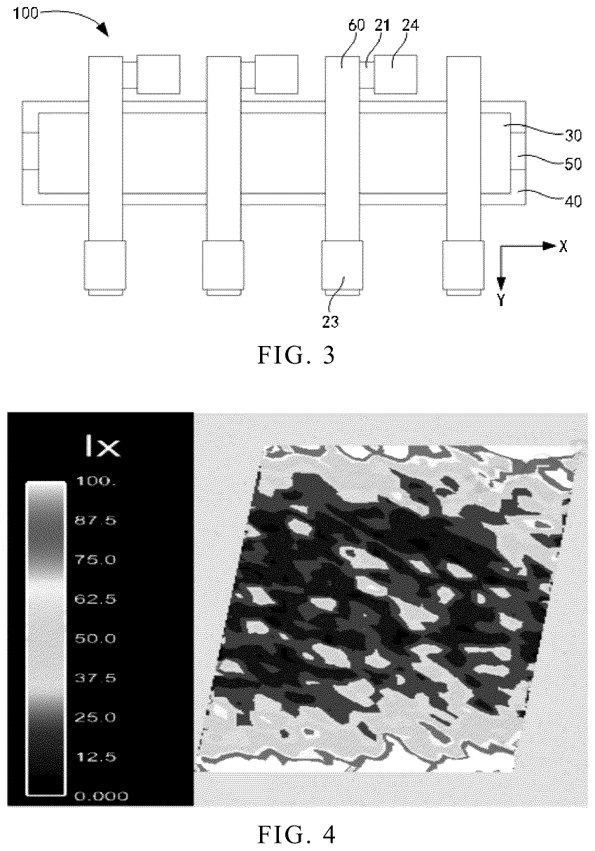

Referring to FIG. 2 and FIG. 3, FIG. 2 is a schematic cross-sectional structural diagram of an array substrate provided by some embodiments of the present disclosure, FIG. 3 is a schematic planar structural diagram of an array substrate provided by some embodiments of the present disclosure. As shown in FIG. 2, an array substrate 100 includes a substrate 10, and a transistor 20 and a first light-shielding portion 30 disposed at a side of the substrate 10. The transistor 20 includes an active layer 21, a source 23, and a drain 24. The source 23 and the drain 24 are disposed at a side of the active layer 21 away from the substrate 10. The active layer 21 includes a channel region 211. The first light-shielding portion 30 is disposed between the source 23 and the active layer 21, and between the drain 24 and the active layer 21. An orthographic projection of the first light-shielding portion 30 on the substrate 10 covers an orthographic projection of the channel region 211 on the substrate 10 and exceeds a range of the orthographic projection of the channel region 211 on the substrate 10.

In the embodiments, by setting the first light-shielding portion 30 between the source 23 and the active layer 21, and between the drain 24 and the active layer 21, the first light-shielding portion 30 can shield the light reflected from the metal layer where the source 23 and the drain 24 are located, so as to reduce light of the backlight reflected into the channel region 211 through the metal layer where the source 23 and the drain 24 are located, thereby reducing the photogenerated leakage current of transistor devices, improving electrical property of the devices, and alleviating the technical problem of crosstalk caused by the increasing of photogenerated leakage current in existing thin film transistor liquid crystal displays.

Referring to FIG. 2 and FIG. 3, the array substrate 100 further includes a second light-shielding portion 40 disposed between the substrate 10 and the transistor 20. The second light-shielding portion 40 is disposed corresponding to the active layer 21. The substrate 10 can be a rigid substrate or a flexible substrate. In some embodiments, the substrate 10 is a rigid substrate, which may include a hard substrate such as a glass substrate, a quartz substrate, or a silicon wafer. In some embodiments, the substrate 10 is a flexible substrate, which may include a flexible substrate such as a polyimide (PI) film, an ultra-thin glass film, or the like.

The second light-shielding portion 40 is configured to shield the light below the active layer 21, avoiding light from the backlight source to the active layer 21. In the present disclosure, the term “below the active layer 21” refers to a side of the active layer 21 away from the source 23. Similarly, a side of the active layer 21 away from the substrate 10 is above the active layer 21. The first light-shielding portion 30 is configured to shield the light above the active layer 21, so as to reduce light of the backlight reflected into the channel region 211 through the metal layer where the source 23 and the drain 24 are located.

Alternatively, a material of the first light-shielding portion 30 and a material of the second light-shielding portion 40 are the same. For example, both of the first light-shielding portion 30 and the second light-shielding portion 40 are metal layers with light-shielding performance, but the present disclosure is not limited to these. In some embodiments of the present disclosure, the material of the first light-shielding portion 30 and the material of the second light-shielding portion 40 can also be other materials with light-shielding performance, such as a black matrix (BM). The material of the first light-shielding portion 30 and the material of the second light-shielding portion 40 may also be different in other embodiments.

Alternatively, a buffer layer 11 is disposed between the second light-shielding portion 40 and the active layer 21. The buffer layer 11 can prevent unexpected impurities or pollutants (such as moisture, oxygen, and the like.) from spreading from the substrate 10 to devices that may be damaged by these impurities or pollutants, and provide a flat top surface. The buffer layer 11 may include silicon nitride (SiNx) or silicon oxide (SiOx), or may be a laminated layer composed of silicon nitride and silicon oxide.

The transistor 20 is disposed at a side of the buffer layer 11 away from the substrate 10. The transistor 20 is a thin film transistor 20. The active layer 21 of the transistor 20 is disposed on the buffer layer 11. A material of the active layer 21 includes polycrystalline silicon (p-Si), for example, low-temperature polycrystalline silicon (LTPS). The active layer 21 includes a channel region 211, and a source-doped region 212 and a drain-doped region 213 disposed at opposite two sides of the channel region 211. Each of the source-doped region 212 and the drain-doped region 213 includes a heavily doped region and a lightly doped region. The heavily doped region is disposed at a side of the lightly doped region away from the channel region 211. For example, the source-doped region 212 includes a heavily doped region 2121 and a lightly doped region 2122, and the drain-doped region 213 includes a heavily doped region 2131 and a lightly doped region 2132.

Continuing with reference to FIG. 2, the transistor 20 further includes a gate 22 disposed at a side of the active layer 21 away from the substrate 10. The gate 22 is disposed corresponding to the channel region 211. The first light-shielding portion 30 is disposed at a side of the gate 22 away from the substrate 10. The orthographic projection of the first light-shielding portion 30 on the substrate 10 covers an orthographic projection of the gate 22 on the substrate 10 and exceeds a range of the orthographic projection of the gate 22 on the substrate 10.

The array substrate 100 further includes a gate insulation layer 12 covering the active layer 21 and the buffer layer 11. The gate insulation layer 12 may include silicon nitride (SiNx) or silicon oxide (SiOx), or may be a laminated layer composed of silicon nitride and silicon oxide. The gate 22 is disposed at a side of the gate insulation layer 12 away from the substrate 10. The orthographic projection of the gate 22 on the substrate 10 overlaps with the orthographic projection of the channel region 211 on the substrate 10. The gate 22 is a single layer or a laminated layer composed of metals such as Mo, Al, Cu, Ti, or alloys of these metals.

The array substrate 100 further includes a first interlayer insulation layer 13 covering the gate 22 and the gate insulation layer 12. The first interlayer insulation layer 13 may include silicon nitride (SiNx) or silicon oxide (SiOx), or may be a laminated layer composed of silicon nitride and silicon oxide. The first light-shielding portion 30 is disposed at a side of the first interlayer insulation layer 13 away from the substrate 10.

The array substrate 100 further includes a second interlayer insulation layer 14 covering the first light-shielding portion 30 and the first interlayer insulation layer 13. The second interlayer insulation layer 14 may include silicon nitride (SiNx) or silicon oxide (SiOx), or may be a laminated layer composed of silicon nitride and silicon oxide. The source 23 and the drain 24 are disposed at a side of the second interlayer insulation layer 14 away from the substrate 10. The source 23 is connected to the source-doped region 212 of the active layer 21 through one via hole of the second interlayer insulation layer 14, and the drain 24 is connected to the drain-doped region 213 of the active layer 21 through another via hole of the second interlayer insulation layer 14. More specifically, the source 23 is connected to the heavily doped region 2121 of the source-doped region 212 through one via hole of the second interlayer insulation layer 14, and the drain 24 is connected to the heavily doped region 2131 of the drain-doped region 213 through another via hole of the second interlayer insulation layer 14, which can reduce the contact impedance between the source 23 and the source-doped region 212, as well as the contact impedance between the drain 24 and the drain-doped region 213.

The source 23 and the drain 24 are disposed in the same layer, and materials of the source 23 and the drain 24 are the same. For example, both of the source 23 and the drain 24 are single layers or laminated layers composed of metals such as Mo, Al, Cu, Ti, or alloys of these metals. In the present disclosure, the term “disposed in the same layer” indicates that a film layer formed by the same material in a preparation process is patterned to obtain at least two different components. For example, the source 23 and the drain 24 in the embodiments are formed by patterning the same conductive film layer, and thus the source 23 and the drain 24 are disposed in the same layer.

In some embodiments of the present disclosure, the array substrate 100 further includes a passivation layer, a planarization layer, and a pixel electrode disposed at a side of the source 23 and the drain 24 away from the substrate 10. The planarization layer is disposed at a side of the passivation layer away from the substrate 10. The pixel electrode is disposed at a side of the planarization layer away from the substrate 10.

In the embodiments of the present disclosure, by setting the first light-shielding portion 30 between the source 23 and the active layer 21, and between the drain 24 and the active layer 21, the first light-shielding portion 30 can shield the reflected light from the metal layer where the source 23 and the drain 24 are located, so as to reduce light of the backlight reflected into the channel region 211 through the metal layer where the source 23 and the drain 24 are located, thereby reducing the photogenerated leakage current of transistor devices and improving the electrical property of the devices. Moreover, by setting the first light-shielding portion 30, it is necessary for the first interlayer insulation layer 13 and the second interlayer insulation layer 14 to be disposed between the gate 22 and the source 23, and between the gate 22 and the drain 24. Compared with the single insulation layer between the gate 22 and the source 23, and between the gate 22 and the drain 24 in FIG. 1, the embodiments increase a distance between the gate 22 and the source 23, and between the gate 22 and the drain 24, which makes the light in the reflected light from the metal layer where the source 23 and the drain 24 are located that is not originally shielded by the gate 22 is shielded by the gate 22, thereby further reducing light of the backlight reflected into the channel region 211 through the metal layer where the source 23 and the drain 24 are located, and thus further reducing photogenerated leakage current of the transistor devices.

Specific structures of the first light-shielding portion 30 will be described in detail in the following.

Referring to FIG. 3, the array substrate 100 further includes multiple gate scanning lines 50 extending along a first direction X and multiple data lines 60 extending along a second direction Y. One of the gate scanning lines 50 is connected to the gate 22 and disposed in the same layer as the gate 22. Alternatively, one of the gate scanning lines 50 and the gate 22 are integrally disposed, that is, a part of one of the gate scanning lines 50 overlapping with the active layer 21 is the gate 22 of each transistor 20. A part of the active layer 21 overlapping with one of the gate scanning lines 50 is the channel region 211 of the active layer 21. Along the second direction Y, an orthographic projection of one of the gate scanning lines 50 on the substrate 10 is located within an orthographic projection of the second light-shielding portion 40 on the substrate 10, and a width of one of the gate scanning lines 50 is less than a width of the second light-shielding portion 40, so that the second light-shielding portion 40 can shield light from shining on the active layer 21. One of the data lines 60 is connected to the source 23 and disposed in the same layer as the source 23. Alternatively, one of the data lines 60 and the source 23 are integrally disposed, that is, a part of one of the data lines 60 connected to the active layer 21 is the source 23 of the transistor 20. Along the first direction X, an orthographic projection of one of the data lines 60 on the substrate 10 covers an orthographic projection of the active layer 21 on the substrate 10, and a width of one of the data lines 60 is greater than a width of the active layer 21, so that one of the data lines 60 can shield external light from shining on the channel region 211 of the active layer 21.

The first light-shielding portion 30 extends along the first direction X. The orthographic projection of the first light-shielding portion 30 on the substrate 10 covers the orthographic projection of one of the gate scanning lines 50 on the substrate 10 and exceeds a range of the orthographic projection of one of the gate scanning lines 50 on the substrate 10 along the second direction Y. That is, a width of the first light-shielding portion 30 is greater than a width of one of the gate scanning lines 50 along the second direction Y. Alternatively, the orthographic projection of the first light-shielding portion 30 on the substrate 10 is located within the orthographic projection of the second light-shielding portion 40 on the substrate 10, and the width of the first light-shielding portion 30 is less than the width of the second light-shielding portion 40 along the second direction Y.

Alternatively, the first light-shielding portion 30 is in a strip shape along the first direction X to better shield the reflected light from the metal layer where the source 23 and the drain 24 are located.

Further description through simulation will be provided to demonstrate that the array substrate 100 of the embodiments can achieve the effect of reducing light of the backlight reflected into the channel region 211 through the metal layer where the source 23 and the drain 24 are located in the following.

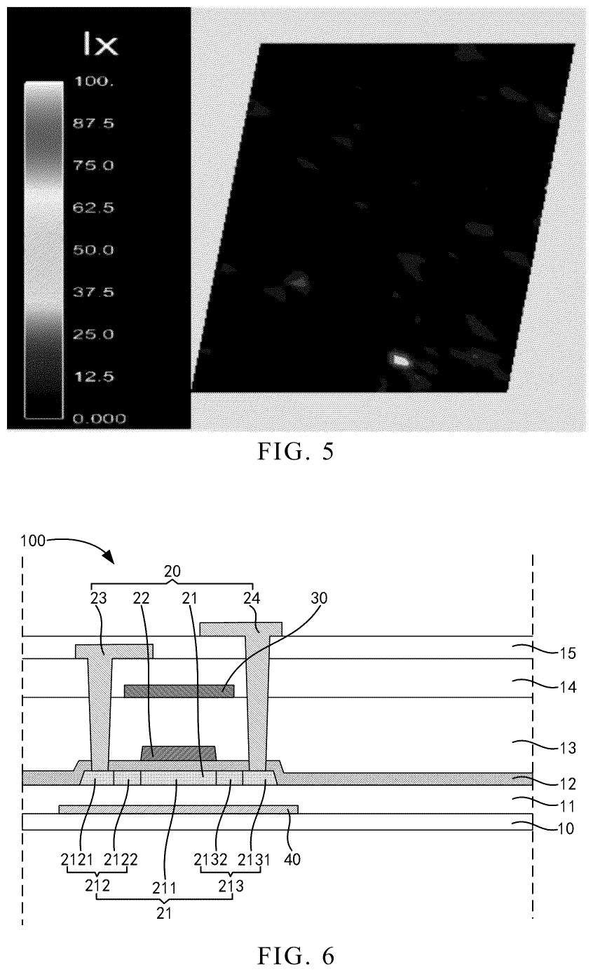

Referring to FIGS. 1 to 5, FIG. 4 is a schematic diagram of a light-leakage distribution of the array substrate in FIG. 1, FIG. 5 is a schematic diagram of a light-leakage distribution of the array substrate in FIG. 3. The array substrate in FIG. 1 is not equipped with the first light-shielding portion 30 of the array substrate 100 in FIG. 2. Comparing FIG. 4 and FIG. 5, it can be seen that the channel region 211′ in FIG. 1 has more light of leakage, and the channel region 211′ receives larger light intensity of leakage, which reaches 1.66E-4. The embodiments of the present disclosure can greatly reduce light of the backlight reflected into the channel region 211 through the metal layer where the source 23 and the drain 24 are located by setting the first light-shielding portion 30, thereby reducing light intensity of the leakage received by the channel region 211. Specifically, the light intensity of the leakage is reduced to 1.68E-5 such that the light intensity of the leakage received by the channel region 211 of the array substrate 100 in the embodiments is reduced to 12% of the array substrate without setting the first light-shielding portion 30. It can be seen that, light of the backlight reflected into the channel region 211 through the metal layer where the source 23 and the drain 24 are located can be greatly reduced by setting the first light-shielding portion 30, thereby reducing the photogenerated leakage current of transistor devices, improving the electrical property of the devices, and alleviating the technical problem of crosstalk caused by the increasing of photogenerated leakage current in existing thin film transistor liquid crystal displays.

In some embodiments, referring to FIGS. 2 to 6, FIG. 6 is another schematic cross-sectional structural diagram of an array substrate provided by some embodiments of the present disclosure. These embodiments are different from the above embodiments in that the drain 24 is disposed at a side of the source 23 away from the substrate 10. That is, the source 23 and the drain 24 are disposed in different layers and formed by different metal layers. The array substrate 100 further includes a third interlayer insulation layer 15 covering the source 23 and the second interlayer insulation layer 14. The drain 24 is disposed at a side of the third interlayer insulation layer 15 away from the substrate 10. The drain 24 is connected to the drain-doped region 213 of the active layer 21 through a via hole of the third interlayer insulation layer 15.

In the embodiments, by setting the source 23 and the drain 24 in different layers, the wiring space in the array substrate 100 can be increased, which is more conducive to achieving high pixel density. Moreover, the distance between the gate 22 and the drain 24 can be increased by setting the source 23 and the drain 24 in different layers, which makes the light in the reflected light from the metal layer where the drain 24 is located that is not originally shielded by the gate 22 is shielded by the gate 22, thereby further reducing light of the backlight reflected into the channel region 211 through the metal layer where the source 23 and the drain 24 are located, and thus further reducing photogenerated leakage current of the transistor devices. Other descriptions can refer to the above embodiments, which will not be repeated here.

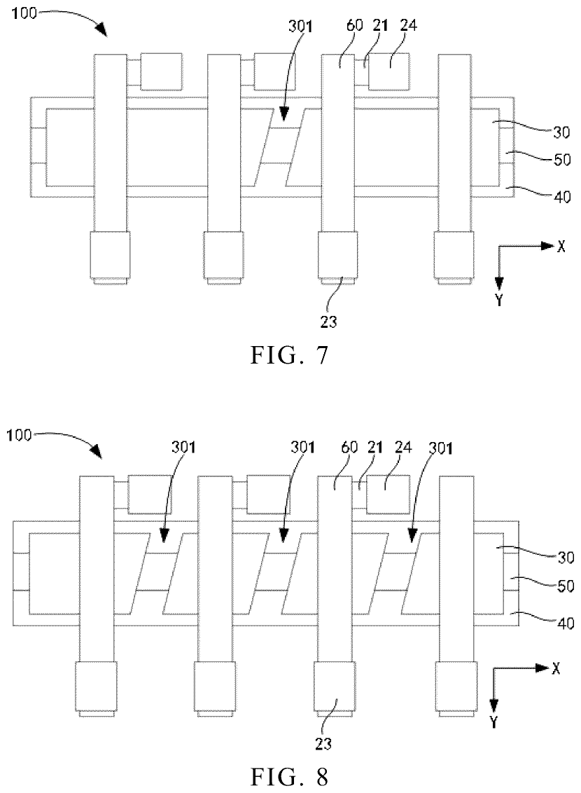

In some embodiments, referring to FIGS. 2 to 7, FIG. 7 is another schematic planar structural diagram of the array substrate 100 provided by some embodiments of the present disclosure. These embodiments are different from the above embodiments in that the first light-shielding portion 30 is provided with at least one fracture 301 disposed between adjacent two data lines 60, and the first light-shielding portions 30 disposed at two sides of the fracture 301 are separated from each other. By setting the fracture 301 in the first light-shielding portion 30, the first light-shielding portion 30 can be divided into two separate parts, thereby reducing accumulation of static electricity on the first light-shielding portion 30, and thus reducing probability of poor electrostatic discharge (ESD). Other descriptions can refer to the above embodiments, which will not be repeated here.

In some embodiments, referring to FIGS. 2 to 8, FIG. 8 is another schematic planar structural diagram of the array substrate 100 provided by some embodiments of the present disclosure. These embodiments are different from the above embodiments in that the fracture 301 is disposed between every adjacent two data lines 60. Compared with the above embodiments, the first light-shielding portion 30 in these embodiments is equipped with more fractures 301, which can further reduce the accumulation of static electricity on the first light-shielding portion 30, thereby further reducing the probability of poor electrostatic discharge.

Similarly, further description through simulation will be provided to demonstrate that the array substrate 100 of the embodiments can achieve the effect of reducing light of the backlight reflected into the channel region 211 through the metal layer where the source 23 and the drain 24 are located in the following.

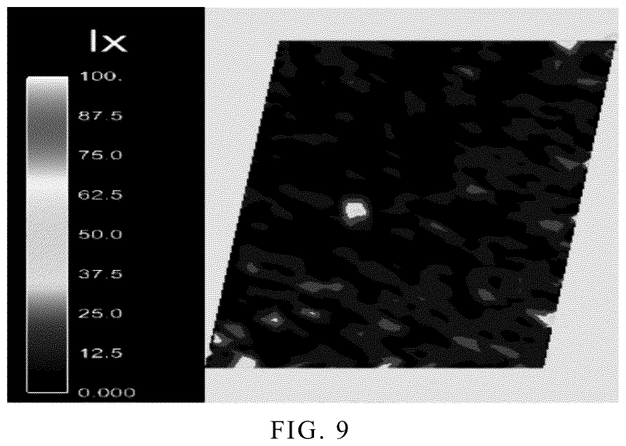

Referring to FIGS. 1 to 9, FIG. 9 is a schematic diagram of a light-leakage distribution of the array substrate in FIG. 8. Comparing FIG. 4 and FIG. 9, it can be seen that the channel region 211′of the array substrate in FIG. 1 has more light of leakage, and the channel region 211′receives larger light intensity of leakage, which reaches 1.66E-4. The embodiments of the present disclosure can greatly reduce light of the backlight reflected into the channel region 211 through the metal layer where the source 23 and the drain 24 are located by setting the first light-shielding portion 30, thereby reducing light intensity of the leakage received by the channel region 211. Specifically, light intensity of the leakage is reduced to 4.75E-5 such that the light intensity of the leakage received by the channel region 211 of the array substrate 100 in the embodiments is reduced to 29% of the array substrate without setting the first light-shielding portion 30. It can be seen that, light of the backlight reflected into the channel region 211 through the metal layer where the source 23 and the drain 24 are located can be greatly reduced by setting the first light-shielding portion 30, thereby reducing the photogenerated leakage current of transistor devices, improving the electrical property of the devices, and alleviating the technical problem of crosstalk caused by the increasing of photogenerated leakage current in existing thin film transistor liquid crystal displays. Other descriptions can refer to the above embodiments, which will not be repeated here.

Based on the invention concept, some embodiments of the present disclosure further provide a display panel, which includes any of array substrates 100 in the above-mentioned embodiments. Alternatively, the display panel is a liquid crystal display panel, which further includes an opposed substrate disposed opposite to the array substrate 100 and a liquid crystal layer disposed between the array substrate 100 and the opposed substrate. The opposed substrate can be a color film substrate.

According to the above-mentioned embodiments, it can be seen that:

In the array substrate and the display panel provided in the present disclosure, the array substrate includes the substrate, and the transistor and the first light-shielding portion disposed at a side of the substrate; the transistor includes the active layer, the source, and the drain; the source and the drain are disposed at a side of the active layer away from the substrate; the active layer includes the channel region; the first light-shielding portion is disposed between the source and the active layer, and between the drain and the active layer; and the orthographic projection of the first light-shielding portion on the substrate covers the orthographic projection of the channel region on the substrate, and exceeds a range of the orthographic projection of the channel region on the substrate. By setting the first light-shielding portion between the source and the drain and the active layer, the first light-shielding portion of the present disclosure can shield the light reflected from the metal layer where the source and drains are located, so as to reduce light of the backlight reflected into the channel region through the metal layer where the source and the drain are located, thereby reducing the photogenerated leakage current of transistor devices, improving electrical property of the devices, and alleviating the technical problem of crosstalk caused by the increasing of photogenerated leakage current in existing thin film transistor liquid crystal displays.

In the above-mentioned embodiments, the descriptions of each embodiment have its own emphasis. For parts that are not detailed in some embodiments, please refer to relevant descriptions of other embodiments.

The above provides a detailed description to the embodiments of the present disclosure. Specific embodiments are applied in this context to explain the principle(s) and implementation methods of the present disclosure. The description of the above-mentioned embodiments is only used to help understand the technical solutions and core ideas of the present disclosure. Ordinary skilled in the art can understand that they can still modify the technical solutions recorded in the above-mentioned embodiments, or equivalently replace some of the technical features; and these modifications or replacements do not separate the essence of the corresponding technical solutions from the scope of the technical solutions of various embodiments of the present disclosure.

1. An array substrate comprising:
a substrate;
a transistor disposed at a side of the substrate and comprising an active layer, a source, and a drain, wherein the source and the drain are disposed at a side of the active layer away from the substrate, and the active layer comprises a channel region; and
a first light-shielding portion disposed between the source and the active layer, and between the drain and the active layer, wherein an orthographic projection of the first light-shielding portion on the substrate covers an orthographic projection of the channel region on the substrate, and exceeds a range of the orthographic projection of the channel region on the substrate.

2. The array substrate of claim 1, wherein the transistor further comprises a gate disposed at a side of the active layer away from the substrate and corresponding to the channel region, and the first light-shielding portion is disposed at a side of the gate away from the substrate; and wherein the orthographic projection of the first light-shielding portion on the substrate covers an orthographic projection of the gate on the substrate and exceeds a range of the orthographic projection of the gate on the substrate.

3. The array substrate of claim 2, further comprising a plurality of gate scanning lines extending along a first direction and a plurality of data lines extending along a second direction, wherein one of the gate scanning lines is connected to the gate and disposed in a same layer as the gate, and one of the data lines is connected to the source and disposed in a same layer as the source; and
wherein the first light-shielding portion extends along the first direction, and the orthographic projection of the first light-shielding portion on the substrate covers an orthographic projection of one of the gate scanning lines on the substrate and exceeds a range of the orthographic projection of the one of the gate scanning lines on the substrate along the second direction.

4. The array substrate of claim 3, wherein the first light-shielding portion is in a strip shape along the first direction.

5. The array substrate of claim 3, wherein the first light-shielding portion is provided with at least one fracture disposed between adjacent two of the data lines, and parts of the first light-shielding portion at two sides of the fracture are separated from each other.

6. The array substrate of claim 5, wherein the fracture is disposed between every adjacent two of the data lines.

7. The array substrate of claim 1, further comprising a second light-shielding portion disposed between the substrate and the transistor, wherein the second light-shielding portion is disposed corresponding to the active layer.

8. The array substrate of claim 7, wherein the active layer further comprises a source-doped region and a drain-doped region disposed at opposite two sides of the channel region, the source is connected to the source-doped region, and the drain is connected to the drain-doped region; and wherein each of the source-doped region and the drain-doped region comprises a heavily doped region and a lightly doped region, and the heavily doped region is disposed at a side of the lightly doped region away from the channel region.

9. The array substrate of claim 8, wherein the drain is disposed at a side of the source away from the substrate.

10. The array substrate of claim 7, wherein a material of the second light-shielding portion and a material of the first light-shielding portion are the same.

11. A display panel comprising an array substrate, wherein the array substrate comprises:
a substrate;
a transistor disposed at a side of the substrate and comprising an active layer, a source, and a drain, wherein the source and the drain are disposed at a side of the active layer away from the substrate, and the active layer comprises a channel region; and
a first light-shielding portion disposed between the source and the active layer, and between the drain and the active layer, wherein an orthographic projection of the first light-shielding portion on the substrate covers an orthographic projection of the channel region on the substrate, and exceeds a range of the orthographic projection of the channel region on the substrate.

12. The display panel of claim 11, wherein the transistor further comprises a gate disposed at a side of the active layer away from the substrate and corresponding to the channel region, and the first light-shielding portion is disposed at a side of the gate away from the substrate; and wherein the orthographic projection of the first light-shielding portion on the substrate covers an orthographic projection of the gate on the substrate and exceeds a range of the orthographic projection of the gate on the substrate.

13. The display panel of claim 12, further comprising a plurality of gate scanning lines extending along a first direction and a plurality of data lines extending along a second direction, wherein one of the gate scanning lines is connected to the gate and disposed in a same layer as the gate, and one of the data lines is connected to the source and disposed in a same layer as the source; and
wherein the first light-shielding portion extends along the first direction, and the orthographic projection of the first light-shielding portion on the substrate covers an orthographic projection of one of the gate scanning lines on the substrate and exceeds a range of the orthographic projection of the one of the gate scanning lines on the substrate along the second direction.

14. The display panel of claim 13, wherein the first light-shielding portion is in a strip shape along the first direction.

15. The display panel of claim 13, wherein the first light-shielding portion is provided with at least one fracture disposed between adjacent two of the data lines, and parts of the first light-shielding portion at two sides of the fracture are separated from each other.

16. The display panel of claim 15, wherein the fracture is disposed between every adjacent two of the data lines.

17. The display panel of claim 11, further comprising a second light-shielding portion disposed between the substrate and the transistor, wherein the second light-shielding portion is disposed corresponding to the active layer.

18. The display panel of claim 17, wherein the active layer further comprises a source-doped region and a drain-doped region disposed at opposite two sides of the channel region, the source is connected to the source-doped region, and the drain is connected to the drain-doped region; and wherein each of the source-doped region and the drain-doped region comprises a heavily doped region and a lightly doped region, and the heavily doped region is disposed at a side of the lightly doped region away from the channel region.

19. The display panel of claim 18, wherein the drain is disposed at a side of the source away from the substrate.

20. The display panel of claim 17, wherein a material of the second light-shielding portion and a material of the first light-shielding portion are the same.
